(19) United States
(12) Patent Application Publication
(10) Pub. No.: US 2008/0070126 A1
(43) Pub. Date: Mar. 20, 2008

(54) Patterning masks, methods, and systems

(76) Inventor: Yayi Wei, Altamont, NY (US)

Correspondence Address: SLATER & MATSIL LLP, 17950 PRESTON ROAD, SUITE 1000, DALLAS, TX, 75252, US

(21) Appl. No.: 11/523,676

(22) Filed: Sep. 19, 2006

(51) Int. Cl. G03C 5/00; G03F 1/00

(52) U.S. Cl. 430/5; 430/394; 430/311; 430/312; 430/313

(57) ABSTRACT

Masks for patterning material layers of semiconductor devices, methods of manufacturing semiconductor devices, and lithography systems are disclosed. In a preferred embodiment, a method of manufacturing a semiconductor device includes providing a lithography mask, the lithography mask including at least one attenuation region. The at least one attenuation region includes an array of sub-resolution features. A workpiece is provided, the workpiece having a layer of photosensitive material disposed thereon. The layer of photosensitive material is affected using the lithography mask.

### TECHNICAL FIELD

The present invention relates generally to the fabrication of semiconductor devices, and more particularly to lithography masks for patterning material layers of semiconductor devices.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (IC's). There may be a plurality of transistors, memory devices, switches, conductive lines, diodes, capacitors, logic circuits, and other electronic components formed on a single die or chip, for example.

Optical photolithography involves projecting or transmitting light through a pattern made of optically opaque areas and optically clear areas on a mask or reticle. For many years in the semiconductor industry, optical lithography techniques such as contact printing, proximity printing, and projection printing have been used to pattern material layers of integrated circuits. Projection printing is commonly used in the semiconductor industry using wavelengths of 248 nm or 193 nm, as examples. At such wavelengths, lens projection systems and transmission lithography masks are used for patterning, wherein light is passed through the lithography mask to impinge upon a semiconductor wafer or workpiece.

As features of semiconductor devices become smaller, it becomes more difficult to pattern material layers because of diffraction and other effects that occur during the lithography process. In particular, lithography techniques used to pattern the various material layers become challenging as features of semiconductor devices shrink.

Thus, what are needed in the art are improved lithography techniques and lithography masks that are capable of patterning smaller features of semiconductor devices, and that are capable of more accurately printing features of material layers.

### SUMMARY OF THE INVENTION

These and other problems are generally solved or circumvented, and technical advantages are generally achieved, by preferred embodiments of the present invention, which provide novel methods of patterning semiconductor devices, novel lithography masks and systems, and methods of manufacturing lithography masks.

In accordance with a preferred embodiment of the present invention, a method of manufacturing a semiconductor device includes providing a lithography mask, the lithography mask including at least one attenuation region. The at least one attenuation region includes an array of sub-resolution features. A workpiece is provided, the workpiece having a layer of photosensitive material disposed thereon. The layer of photosensitive material is affected using the lithography mask.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a portion of a novel lithography mask comprising an attenuation region implemented in a bright field mask in accordance with a preferred embodiment of the present invention;

FIG. 2 is a graph showing the effect on intensity of the portion of the lithography mask shown in FIG. 1 as a function of varying ratios of the open area of an attenuating array in the attenuation region;

FIG. 3 is a graph illustrating the relative image intensity in relation to the spatial position of the attenuation region shown in FIG. 1;

FIG. 4 shows an attenuation region implemented in a dark field mask in accordance with an embodiment of the present invention;

FIG. 5 shows a top view of a lithography mask in accordance with a preferred embodiment of the present invention, wherein attenuation regions having varying degrees of attenuation are positioned in a plurality of various locations on the mask;

FIG. 6 shows a lithography mask in accordance with an embodiment of the present invention implemented in a lithography system;

FIG. 7 shows a cross-sectional view of a semiconductor device having a layer of photoresist disposed thereon that has been patterned using a novel lithography mask in accordance with an embodiment of the present invention; and

FIG. 8 shows a cross-sectional view of a semiconductor device having a material layer disposed thereon that has been patterned using a novel lithography mask of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely the patterning of material layers of semiconductor devices. Embodiments of the invention may also be applied, however, to other applications where material layers are patterned, for example, such as semiconductor packaging and other types of technologies. Embodiments of the invention may be implemented in many types of semiconductor devices, such as logic, memory, peripheral circuitry, power applications, and other types of semiconductor devices, as examples.

In optical lithography, light is passed through a patterned lithography mask, and the pattern of the mask is transferred to a semiconductor device by exposing a layer of photosensitive material on the semiconductor device to the light that passes through the lithography mask. The layer of photosensitive material is developed, and the layer of photosensitive material is used as a mask while exposed portions of a material layer or a workpiece of the semiconductor device are etched away.

Binary masks typically comprise an opaque material such as chrome or chromium bonded to an optically transparent material such as quartz. The opaque material is patterned with a desired pattern for a material layer of the semiconductor device. In some semiconductor device designs and lithography methods, other types of lithography masks are implemented, such as phase-shifting masks, in which the thickness or material of phase-shifting masks is varied to achieve phase-shifting of light in regions of the masks.

In some conventional lithography systems and methods, diffraction causes light or energy to pass through the mask in unintended locations on the mask. Another type of lithography mask is an attenuating mask, where a film of light attenuating material such as molybdenum (Mo) and silicon (Si) is attached to the mask in predetermined locations, to attenuate or reduce the amount of light passing through the mask or to alter the phase, and to improve the quality of the pattern transfer. However, attenuating masks require the use of an attenuating film that requires an additional material to manufacture the mask. Furthermore, the attenuating films can degrade or become damaged over time.

Embodiments of the present invention achieve technical advantages by providing novel methods and structures for attenuating light or energy in lithography masks. A fine pad array is implemented as an attenuating region in predetermined locations of a lithography mask, to decrease or attenuate the amount of energy that passes through the lithography mask in the attenuating regions.

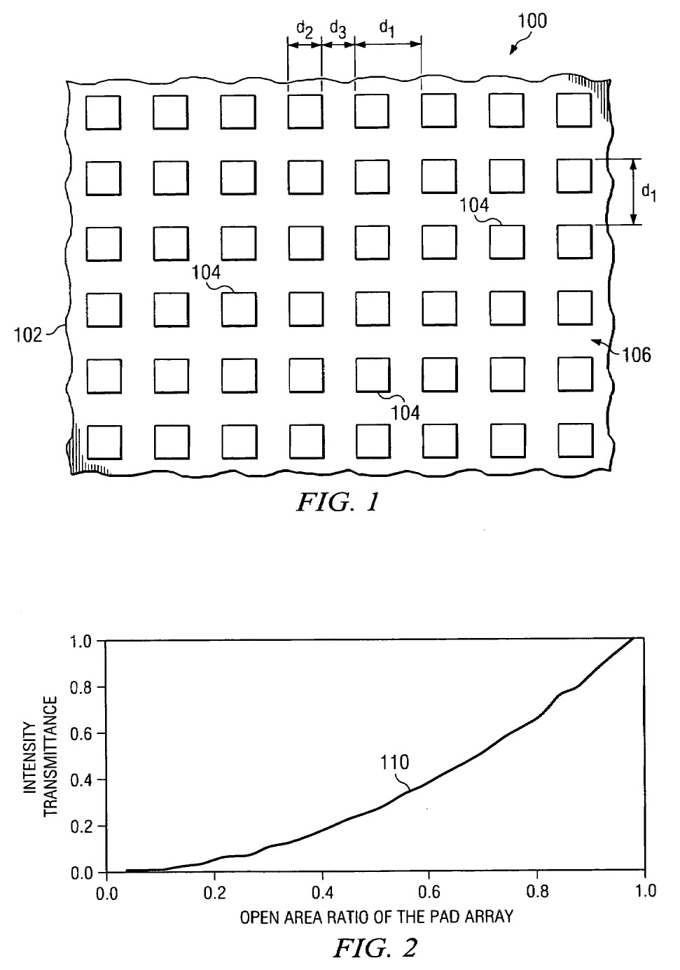

FIG. 1 shows a portion of a novel lithography mask 100 comprising an attenuation region 106 in accordance with a preferred embodiment of the present invention. The attenuation region 106 is also referred to herein as an attenuating region or an energy-attenuating region, for example. The lithography mask 100 comprises a substantially opaque material 104 attached or coupled to a substantially transparent material 102. The substantially opaque material 104 preferably comprises a material opaque to light or energy, such as chromium or other opaque material. The substantially transparent material 102 preferably comprises a transparent material such as quartz, although other materials may also be used.

In the embodiment shown in FIG. 1, the attenuation or attenuating region 106 preferably comprises a plurality of opaque features comprised of the opaque material 104 arranged in an array implemented in a bright field mask 100, as shown. The total distance from one edge of a feature to an edge of an adjacent feature of the opaque material 104, e.g., the pitch of the features of opaque material 104, preferably comprises a dimension d₁. The width of a side of a feature preferably comprises a dimension d₂, and the space between two adjacent features preferably comprises a dimension d₃, as shown.

Dimension d₁ is preferably less than the wavelength of light or energy used to expose a layer of photosensitive material, in accordance with one embodiment of the present invention. Dimension d₁ preferably comprises about 150 nm or less, as an example. Dimensions d₂ and d₃ are preferably less than dimension d₁, and may together total substantially dimension d₁, for example. Dimension d₂ preferably ranges from about 30 to 100 nm, and dimension d₃ preferably ranges from about 30 to 100 nm, as examples. Dimension d₂ and d₃ may comprise about 130 nm or less in other embodiments, as examples. Alternatively, dimensions d₁, d₂, and d₃ may comprise other dimensions, for example.

The features comprised of the opaque material 104 are preferably arranged in a plurality of rows and columns, as shown in FIG. 1. The features may comprise a plurality of opaque squares, as shown, or the features may comprise other shapes, such as a plurality of square, round, elliptical, triangular, rectangular, polygonal, or trapezoidal features. Alternatively, the features may also comprise other shapes, for example. The rows and columns of the features may be aligned, as shown, or they may be staggered, e.g., in alternating rows or columns, or both (not shown). The features preferably comprise a width (e.g., dimension d₂) along at least one side of about 130 nm or less, as an example, although the features may also comprise other dimensions.

A lithography mask 100 including the array of features preferably comprises at least one attenuation region 106. The at least one attenuation region 106 preferably comprises an array of sub-resolution features; e.g., features of the opaque material 104, as shown in FIG. 1. The at least one attenuation region 106 is adapted to reduce an amount of energy transmitted through the lithography mask 100 in the at least one attenuation region 106. The at least one attenuation region 106 may comprise an array of features formed in a substantially opaque material 104 disposed proximate a substantially transparent material 102, as shown in FIG. 1. Alternatively, the at least one attenuation region 208 may comprise an array of substantially transparent features 202 formed in a substantially opaque material 204, e.g., a reverse image of the patterned opaque material 104 shown in FIG. 1, to be described further herein with reference to FIG. 4.

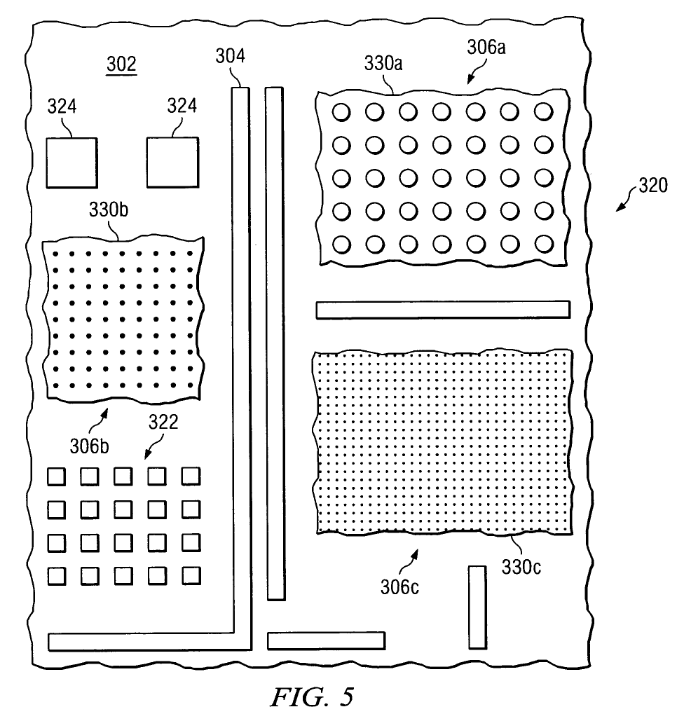

Referring again to FIG. 1, the substantially opaque material 104 of the lithography mask 100 is preferably patterned with at least one attenuation region 106 comprising an array of energy-reducing features that are not reproducible on a layer of photosensitive material affected with the lithography mask 100. The substantially opaque material 104 is preferably also patterned with a plurality of patterns proximate the at least one attenuation region 106 (not shown in FIG. 1; see FIG. 5 at 304, 322, and 324.) The plurality of patterns 304, 322, and 324 may comprise patterns for functional features of a semiconductor device, and the plurality of patterns 304, 322, and 324 are preferably reproducible on a layer of photosensitive material affected with the lithography mask 320, for example.

The sub-resolution, energy-reducing features decrease the amount of light or energy that passes through the attenuation region 106. This is advantageous in some applications by avoiding exposing a region of a layer of photoresist on a semiconductor device proximate the attenuation region 106. In other applications, decreasing the amount of light or energy that passes through the attenuation region 106 improves the patterning of functional features of a semiconductor device proximate the attenuation region 106, for example.

The fine pad array, e.g., the attenuation region 106 of embodiments of the present invention, is used as a light attenuator in a lithography mask 100. For example, a relatively small two-dimensional pad array 106 such as the one shown in FIG. 1 that is not transparent, but rather comprises an array of the features of the opaque material 104, may be used as a light attenuator in a lithography mask 100. Preferably, the pitch of the array is smaller than the resolution limit of the projection optics of the lithography system the lithography mask 100 is used in, so that the array structure is not transferred to a layer of photoresist when the mask 100 pattern is transferred to a semiconductor device. In some embodiments of the present invention, for example, the pitch or the distance d₁ from one edge to an edge of an adjacent feature may be calculated or determined using Equation 1:

d₁<(0.5*NA)/λ; Eq. 1

wherein NA is the numerical aperture of the projection lens system of the lithography system, and wherein λ is the wavelength of a light or energy source used during an exposure process. If the dimension or pitch d₁ between adjacent features of the attenuating array 106 is smaller than the value or amount calculated using Equation 1, then the attenuating array 106 is advantageously not transferred to the pattern formed a semiconductor device, for example. Thus, the dimension d₁ may be selected and determined so that the attenuating array 106 pattern functions as a light or energy attenuator rather than as a scattering object, for example.

Advantageously, the size of the features of the opaque material 104 and the amount of the open area, e.g., the amount of the substantially transparent material 102 left exposed between the features of the opaque material 104, may be varied in accordance with embodiments of the present invention to achieve the desired amount of attenuation. FIG. 2 is a graph 110 from simulation calculations showing the effect on intensity of the portion of the lithography mask 100 shown in FIG. 1 as a function of varying ratios of the open areas of the attenuating array of the attenuation region 106. The transmittance of the attenuation region 106 (e.g., the attenuating array of features) may be determined by calculating a square of the open area ratio. For example, for an array region 106 comprising an open area ratio of about 0.5, the light intensity that is allowed to pass the array region 106 area is about (0.5)²=0.25. Thus, the amount of transmittance of the array region 106 may be determined using Equation 2:

transmittance=(array open area ratio)² Eq. 2

The graph 110 in FIG. 2 shows the variation of intensity transmittance of the pad array, e.g., the array region 106 of FIG. 1, as a function of the open area ratio. In the simulation calculations for the graph 110 shown in FIG. 2, the exposure conditions comprised a KrF laser having a wavelength λ of about 248 nm and a numerical aperture (NA) of about 0.82, for example. The graph 110 illustrates that with an increase in the array open area ratio, the transmission through the array region 106 increases. An open area ratio of about 0.30 to 0.70 corresponds to a transmittance of about 10 to 50%, for example. Thus, the array pitch (e.g., dimension d₁) in this example may be preferably set at about 100 nm, and the pad size, e.g., of features in the array region 106, may be set at about 55 to 80 nm, e.g., measured on a wafer scale, for example.

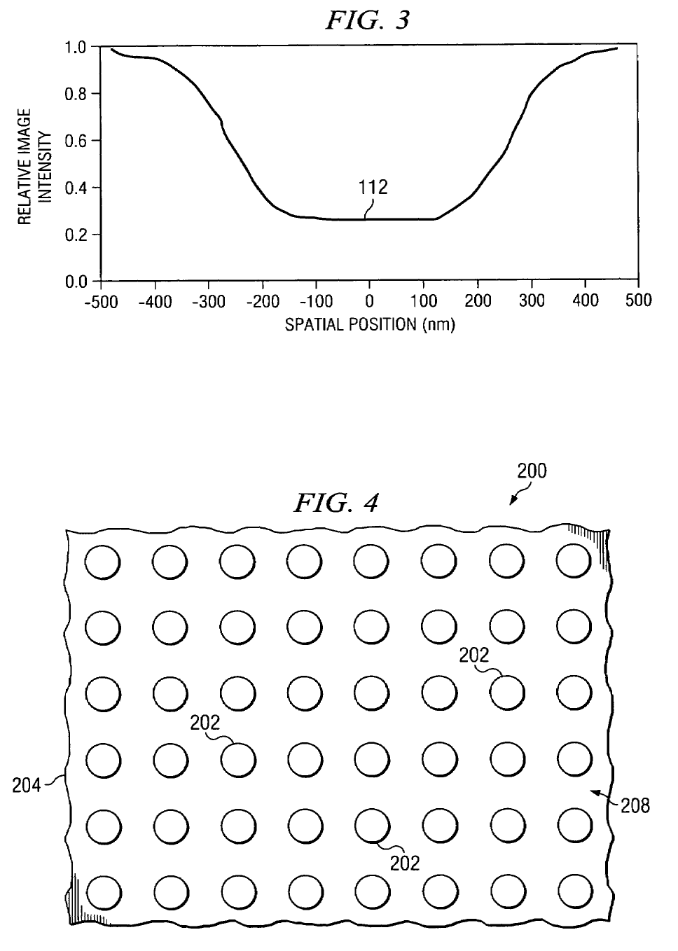

FIG. 3 is a graph 112 of simulation calculations illustrating the relative image intensity in relation to the spatial position of the attenuation region 106 shown in FIG. 1. FIG. 3 shows the light intensity profile obtained from a pad array, e.g., from an array region 106 such as the one shown in FIG. 1. In the simulation calculations for the graph 112, the array region 106 comprised five pads or opaque features of opaque material 104 in the profiled direction. The pitch and size of the pad array was 100 nm and 70 nm, respectively, and the open area ratio of the array was 0.49. The transmission of the pattern was determined to be about 0.24. From the graph 112 in FIG. 3, it can be seen that the light intensity is uniform in the center region covered by the pad array 106. Thus, the novel pad array, e.g., the array region 106 shown in FIG. 1, advantageously functions as a conventional uniform attenuating film, and achieves light attenuation.

FIG. 4 shows an attenuation region 208 implemented in a dark field mask 200 in accordance with an embodiment of the present invention. Like numerals are used for the various elements that were used to describe FIG. 1, and to avoid repetition, each reference number shown in FIG. 4 is not described again in detail herein. In this embodiment, rather than forming an array of opaque features, the attenuation region 208 comprises a grating comprised of a substantially opaque material 204 with a plurality of substantially transparent features 202 formed in the opaque material 204. The attenuation region 208 may comprise a reverse image of the attenuation region 106 shown in FIG. 1, for example.

Note that in FIG. 4, the features comprising the substantially transparent features 202 formed in the substantially opaque material 204 comprise a circular shape; alternatively, the transparent features 202 may comprise squares as shown in FIG. 1, or the transparent features 202 may comprise other shapes in accordance with embodiments of the present invention, as described for features of the opaque material 104 shown in FIG. 1, as examples.

Advantageously, one or more attenuation regions 106 and/or 208 shown in FIGS. 1 and 4, respectively, may be included in a single lithography mask 100 or 200. FIG. 5 shows a top view of a lithography mask 320 in accordance with a preferred embodiment of the present invention, wherein attenuation regions 306a, 306b, and 306c having varying degrees of attenuation are positioned in a plurality of various locations 330a, 330b, and 330c, respectively, on the lithography mask 320. In the embodiment shown, the features of the attenuation regions 306a, 306b, and 306c comprise a plurality of opaque features formed in an opaque material, and patterns for functional portions of a semiconductor device may be formed in other regions of the mask 320 in the opaque material. For example, patterns for conductive lines are shown at 304, patterns for an array of transistor gate contacts are shown at 322, and patterns for capacitor plates are shown at 324. Alternatively, the functional patterns 304, 322, and 324 may comprise other shapes and may comprise patterns for other types of devices and circuit elements, for example, not shown.

In this embodiment, the lithography mask 320 includes at least one attenuation region, and more preferably comprises a plurality of attenuation regions 306a, 306b, and 306c, each of the plurality of attenuation regions 306a, 306b, and 306c being adapted to reduce an amount of energy transmitted through the lithography mask 320 by a predetermined amount. The predetermined amount of energy reduction of each of the plurality of attenuation regions 306a, 306b, and 306c may be different, as shown in FIG. 5, wherein the array density and open area ratio is different for each attenuation region 306a, 306b, and 306c, relative to other of the plurality of the attenuation regions 306a, 306b, and 306c. However, alternatively, the predetermined amount of energy reduction may be the same for some or all of the attention regions 306a, 306b, and 306c of the lithography mask 320 in some embodiments of the present invention, not shown.

For example, in some embodiments, the lithography mask 320 may comprise a first attenuation region 306a adapted to reduce an amount of energy transmitted through the lithography mask 320 in or proximate the first attenuation region 306a by a first amount, and the lithography mask 320 may include at least one second attenuation region 306b and/or 306c adapted to reduce an amount of energy transmitted through the lithography mask 320 in or proximate the at least one second attenuation region 306b and/or 306c by at least one second amount, the at least one second amount being different than the first amount.

As described with reference to FIG. 1, the attenuation regions 306a, 306b, and 306c may comprise an array of substantially opaque features formed in the substantially opaque material 304, as shown in FIG. 5. Alternatively, the attenuation regions 306a, 306b, and 306c may comprise an array of substantially transparent features formed in the substantially opaque material, as shown in FIG. 4; e.g., a reverse image of substantially transparent material 302 being left exposed through the patterned substantially opaque material 304. A combination of both dark field attenuating array regions and bright field attenuating array regions may be implemented on a single lithography mask 320, for example, not shown.

Each of the plurality of attenuation regions 306a, 306b, and 306c is preferably adapted to reduce an amount of energy transmitted through the lithography mask 320 by a predetermined amount of energy, wherein the predetermined amount of energy reduction of each of the plurality of attenuation regions is the same or different than the predetermined amount of energy reduction of other of the plurality of attenuation regions 306a, 306b, and 306c.

Preferably, the plurality of opaque or transparent features comprise the same size within one area, e.g., within each attenuation region 306a, 306b, and 306c. The features are preferably arranged in rows and columns, and are spaced apart by a first dimension d₁, as described with reference to FIG. 1. The features may be spaced apart by different dimensions d, in the various attenuation regions 306a, 306b, and 306c, and the features may also be different sizes and/or shapes, for example, within each attenuation region 306a, 306b, and 306c.

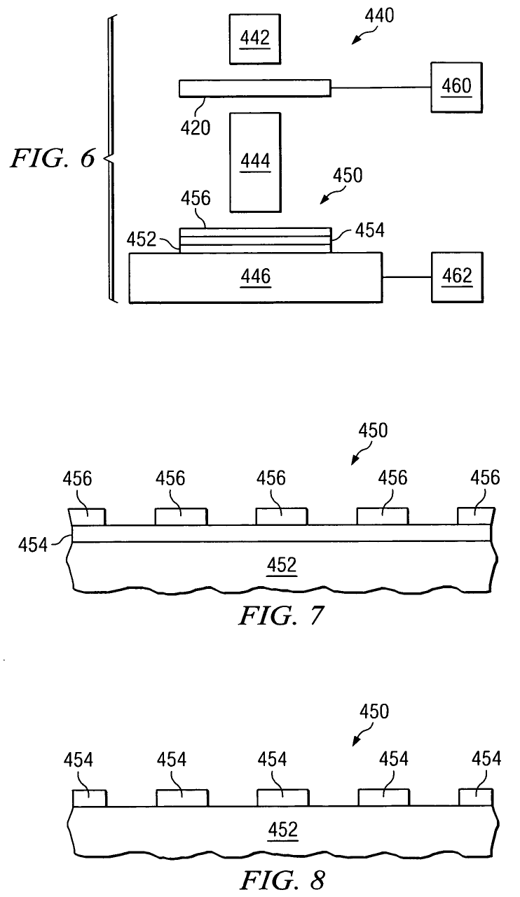

FIG. 6 shows a lithography mask 420 in accordance with an embodiment of the present invention implemented in a lithography system 440. Embodiments of the present invention include lithography systems 440 that include the novel lithography masks 100, 200, 320, and 420 described herein. The lithography system 440 preferably includes an energy source 442, a lithography mask 420 such as the lithography masks 100, 200, and 320 shown in FIGS. 1, 4, and 5, respectively, comprising at least one energy-attenuating region (not shown in FIG. 6; see attenuation regions 106, 208, 306a, 306b, and 306c in FIGS. 1, 4, and 5). The lithography mask 420 is disposed between a projection lens system 444 and the energy source 442. The lithography system 440 includes a support means 446 for a semiconductor device 450. The support means 446 may comprise a wafer support adapted to support a wafer or workpiece 452. The wafer support 446 is also referred to as a wafer stage or exposure chuck, for example.

The lithography system 440 may comprise a scanner that includes a means 460 for moving the lithography mask 420 and a means 462 for moving the wafer support 446, for example, as shown. The means 460 for moving the lithography mask 420 and the means 462 for moving the wafer support 446 may comprise motors or steppers that are preferably synchronized, e.g., so that the lithography mask 420 and wafer support 446 are moved in the same or opposite directions at a predetermined relative speed during an exposure process, for example.

The energy source 442 may comprise a light source or other energy source that is adapted to emit light or energy towards the semiconductor device 450. The projection lens system 444 may comprise a plurality of lenses and/or mirrors that are adapted to direct the energy towards the semiconductor device 450. The semiconductor device 450 includes a workpiece 452 or substrate having a material layer 454 to be patterned disposed thereon. A layer of photosensitive material 456 comprising photoresist, for example, is disposed over the material layer 454.

When energy is directed towards the semiconductor workpiece 450 through the lithography mask 420, the energy passes through the transparent portions of the mask 420 and is blocked by the opaque portions of the mask 420, exposing regions of the layer of photosensitive material 456 of the semiconductor device 450, as shown in a cross-sectional view in FIG. 7. The layer of photosensitive material 456 is developed, and the exposed regions are removed, as shown in FIG. 7. The layer of photosensitive material 456 is then used to pattern the material layer 454, e.g., by etching away exposed portions of the material layer 454 using the layer of photosensitive material 456 as a mask. The layer of photosensitive material 456 is then removed, leaving the patterned material layer 454, as shown in FIG. 8.

Referring again to FIG. 6, when the lithography mask 420 is used to pattern a layer of photosensitive material 456 disposed on the semiconductor device 450, the at least one energy-attenuating region of the lithography mask 420 reduces an amount of energy emitted from the energy source 442 that passes through or proximate the at least one energy-attenuating region of the lithography mask 420. A pattern of the at least one energy-attenuating region of the lithography mask 420 is preferably not transferred to the layer of photosensitive material 456 of the semiconductor device 450 in accordance with preferred embodiments of the present invention.

For example, the patterned regions of the material layer 454 shown in FIG. 8 are formed from the patterns for functional features of the semiconductor device, such as patterns 304, 322, and 324 shown in the lithography mask 320 of FIG. 5. Preferably, the attenuation regions 306a, 306b, and 306c do not result in the formation of features in the material layer 454 (not shown in FIG. 8).

Embodiments of the present invention are particularly useful when implemented in immersion lithography systems, for example, not shown. In these embodiments, referring again to FIG. 6, the lithography system 440 includes a means for disposing a fluid between the projection lens system 444 and the semiconductor device 450, not shown. The fluid, which may comprise de-ionized water or other liquid, is preferably introduced between a last element or lens of the projection lens system 444 and the semiconductor device 450 during the exposure process, e.g., by an immersion head (not shown) clamped to the end of the lens system 444. The fluid may be provided by a nozzle or by input and output ports within the immersion head, for example.

Alternatively, the lithography system 440 may comprise a lithography system that utilizes ultraviolet (UV) or extreme UV (EUV) light, an optical lithography system, an x-ray lithography system, an interference lithography system, or other types of lithography systems, as examples.

Embodiments of the present invention include novel methods of manufacturing semiconductor devices 450 using the novel lithography masks 100, 200, 320, and 420 and systems 440 described herein, and semiconductor devices 450 manufactured using the novel masks 100, 200, 320, and 420 and systems 440. FIG. 7 shows a cross-sectional view of a semiconductor device 450 having a layer of photoresist 456 disposed thereon that has been patterned using a novel lithography mask 100, 200, 320, and 420 in accordance with an embodiment of the present invention. FIG. 8 shows a cross-sectional view of a semiconductor device 450 having a material layer 454 disposed thereon that has been patterned using a novel lithography mask 100, 200, 320, and 420 of the present invention.

For example, referring again to FIGS. 7 and 8, and also referring again to FIGS. 1, 4, 5, and 6, in accordance with an embodiment of the present invention, a method of manufacturing a semiconductor device 450 preferably comprises providing a lithography mask 100, 200, 320, and 420, the lithography mask 100, 200, 320, and 420 comprising at least one attenuation region 106, 208, 306a, 306b, or 306c, the at least one attenuation region 106, 208, 306a, 306b, or 306c comprising an array of sub-resolution features.

The method includes providing a workpiece 452, the workpiece 452 having a layer of photosensitive material 456 disposed thereon, and affecting the layer of photosensitive material 456 using the lithography mask 100, 200, 320, and 420. The workpiece 452 may include a semiconductor substrate comprising silicon or other semiconductor materials covered by an insulating layer, for example. The workpiece 452 may also include other active components or circuits, not shown. The workpiece 452 may comprise silicon oxide over single-crystal silicon, for example. The workpiece 452 may include other conductive layers or other semiconductor elements, e.g., transistors, diodes, etc. Compound semiconductors, GaAs, InP, Si/Ge, or SiC, as examples, may be used in place of silicon. The workpiece 452 may comprise a silicon-on-insulator (SOI) substrate, for example.

A material layer 454 is deposited or formed over the workpiece 452. The material layer 454 may comprise an insulating material, a semiconductive material, or a conductive material, as examples. In some embodiments, the material layer 454 may comprise a conductive material and/or semiconductive material that will be subtractively etched to form conductive lines. In other embodiments, the material layer 454 may comprise an insulating material that will be patterned with the shape of conductive lines and later filled with a conductive and/or semiconductive material to form conductive lines within the patterned insulating material, in a damascene (e.g., a single or dual damascene) process. The conductive lines that will be formed may comprise wordlines or bitlines of a memory device, or conductive lines to connect logic and/or other circuitry, as examples. The material layer 454 may comprise a thickness of about 500 nm or less, although alternatively, the material layer 454 may be greater than 500 nm thick, for example. A layer of photosensitive material 456 is deposited over the material layer 454.

Affecting the layer of photosensitive material 456 using the lithography mask 100, 200, 320, and 420 may include exposing the layer of photosensitive material 456 to energy through the lithography mask 100, 200, 320, and 420, wherein the at least one attenuation region 106, 208, 306a, 306b, or 306c is adapted to reduce the amount of energy transmitted through or proximate the lithography mask 100, 200, 320, and 420 in a region of the layer of photosensitive material 456 proximate the at least one attenuation region 106, 208, 306a, 306b, or 306c.

Affecting the layer of photosensitive material 456 using the lithography mask 100, 200, 320, and 420 preferably comprises not patterning regions of the layer of photosensitive material 456 in locations on the semiconductor device 450 proximate the at least one attenuation region 106, 208, 306a, 306b, or 306c of the lithography mask 100, 200, 320, and 420.

Referring to FIGS. 7 and 8, in a preferred embodiment, a method of manufacturing a semiconductor device includes exposing the layer of photosensitive material 456 using the novel lithography masks 100, 200, 320 and 420 shown in FIGS. 1, 4, 5, and 6, respectively, patterning portions of the layer of photosensitive material 456, developing the layer of photosensitive material 456, and using the layer of photosensitive material 456 to pattern the material layer 454 of the workpiece 452. The material layer 456 may comprise a conductive material, a semiconductive material, or an insulating material, as examples. Embodiments of the present invention include semiconductor devices 450 manufactured in accordance with the novel lithography masks 100, 200, 320, and 420 and systems 420 described herein.

Embodiments of the present invention also include novel methods of manufacturing lithography masks 100, 200, 320, and 420. In accordance with one embodiment, a method of manufacturing a lithography mask 100, 200, 320, and 420 includes determining a layout for a material layer 456 of a semiconductor device 450, determining at least one area of the layout in which to form at least one energy-attenuating region 106, 208, 306a, 306b, or 306c, and determining an amount of energy reduction for the at least one energy-attenuating region 106, 208, 306a, 306b, or 306c. The method includes determining a pattern for the at least one energy-attenuating region 106, 208, 306a, 306b, or 306c that will reduce energy transmitted through the lithography mask 420 by the determined amount of energy reduction, and including the pattern for the at least one energy-attenuating region 106, 208, 306a, 306b, or 306c in the layout of the material layer 456 of the semiconductor device 450 on the lithography mask 100, 200, 320, and 420.

Determining the pattern for the at least one energy-attenuating region 106, 208, 306a, 306b, or 306c may comprise determining a pattern comprising an array of a plurality of opaque or transparent features, and may comprise determining a wavelength λ of energy of a lithography system 440 the lithography mask 100, 200, 320, and 420 will be implemented in. Determining the first dimension d₁ may comprise solving for Equation 1, as previously described herein, for example.

The lithography masks 100 and 200 shown and described herein in FIGS. 1 and 4, respectively comprise binary masks; alternatively, the novel attenuation regions 106 and 208 described herein may be implemented in lithography masks comprising phase shifting masks, alternating phase shifting masks, attenuating phase shifting masks, bright field masks, dark field masks, immersion lithography masks, or combinations thereof with binary masks, as examples.

When the pattern of the lithography mask 100, 200, 320, and 420 is transferred to the semiconductor device 450, advantageously, lines, spaces, and other patterns printed on the layer of photoresist 456, and also on the material layer 454 to be patterned, comprise substantially the desired width. The pattern transfer from the mask 100, 200, 320, and 420 to the semiconductor device 450 is improved by the attenuating regions 106, 208, 306a, 306b, or 306c of embodiments of the present invention.

Advantageously, because the light or energy during the exposure process is attenuated in the attenuating regions 106, 208, 306a, 306b, or 306c, the exposure process for the desired patterns of the lithography mask 100, 200, 320, and 420 is improved. Furthermore, exposure of the attenuation regions 106, 208, 306a, 306b, or 306c is avoided, due to the novel sub-resolution energy-reducing arrays of attenuating features of embodiments of the present invention.

Note that the material layer 454 of the semiconductor device 450 may include a hard mask disposed over a layer of material to be patterned, not shown. In some embodiments, for example, the layer of photosensitive material 456 is patterned using the lithography mask, and then the layer of photosensitive material 456 is used to pattern the hard mask. The layer of photosensitive material 456 is then removed, and the hard mask is used to pattern the material layer 454, for example. Or, the layer of photosensitive material 456 may be left remaining over the hard mask, and both the layer of photosensitive material 456 and the hard mask may be used to pattern the material layer 454, for example.

The lithography masks 100, 200, 320, and 420, systems 440, and lithography methods described herein may be used to fabricate many types of semiconductor devices 450, including memory devices and logic devices, as examples, although other types of semiconductor devices, integrated circuits, and circuitry may be fabricated using the novel embodiments of the present invention described herein. Embodiments of the present invention may be implemented in lithography systems 440 using light at a wavelength of 193 nm, for example, although alternatively, other wavelengths of light or energy may also be used.

Advantages of embodiments of the present invention include providing novel methods of energy attenuation in lithography masks 100, 200, 320, and 420. Using a fine pad array as a light or energy attenuator in a lithography mask 100, 200, 320, and 420 provides lithography mask manufacturers with a large amount of convenience in designing a mask 100, 200, 320, and 420 layout. The novel energy-attenuating pad array regions 106, 208, 306a, 306b, or 306c can be introduced into a local mask 100, 200, 320, and 420 area in locations where light attenuating is needed.

Advantageously, attenuating films are not required; rather, the attenuation regions 106, 208, 306a, 306b, or 306c are formed in material layers of lithography masks 100, 200, 320, and 420 that are typically used in lithography mask fabrication. Thus, additional material layers and films are not required to achieve the novel attenuation regions 106, 208, 306a, 306b, or 306c and arrays described herein. Because the attenuation regions 106, 208, 306a, 306b, or 306c are formed by patterning the opaque material of a lithography mask 100, 200, 320, and 420, the attenuation regions provided a robust and durable means of attenuation in localized regions of the lithography masks 100, 200, 320, and 420.

Improved pattern transfer and semiconductor devices having improved feature dimensions are achievable by the use of the embodiments of the present invention described herein. The novel attenuation regions 106, 208, 306a, 306b, or 306c provide a cost-effective means of providing local energy attenuation in lithography masks 100, 200, 320, and 420.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of manufacturing a semiconductor device, the method comprising:
providing a lithography mask, the lithography mask comprising at least one attenuation region, the at least one attenuation region comprising an array of sub-resolution features;
providing a workpiece, the workpiece having a layer of photosensitive material disposed thereon; and
affecting the layer of photosensitive material using the lithography mask.

2. The method according to claim 1, wherein affecting the layer of photosensitive material using the lithography mask comprises exposing the layer of photosensitive material to energy through the lithography mask, wherein the at least one attenuation region is adapted to reduce the amount of energy transmitted through the lithography mask in a region of the layer of photosensitive material proximate the at least one attenuation region.

3. The method according to claim 1, wherein affecting the layer of photosensitive material using the lithography mask comprises not patterning regions of the layer of photosensitive material in locations on the semiconductor device proximate the at least one attenuation region of the lithography mask.

4. The method according to claim 1, wherein providing the workpiece comprises providing a workpiece having a material layer disposed thereon, the layer of photosensitive material being disposed over the material layer, further comprising:
exposing the layer of photosensitive material, patterning portions of the layer of photosensitive material;
developing the layer of photosensitive material; and
using the layer of photosensitive material to pattern the material layer of the workpiece.

5. The method according to claim 4, wherein providing the workpiece comprises providing a workpiece having a material layer disposed thereon comprising a conductive material, a semiconductive material, or an insulating material.

6. A semiconductor device manufactured in accordance with claim 5.

7. A lithography mask, comprising:
at least one attenuation region, the at least one attenuation region comprising an array of sub-resolution features, wherein the at least one attenuation region is adapted to reduce an amount of energy transmitted through the lithography mask proximate the at least one attenuation region.

8. The lithography mask according to claim 7, wherein the lithography mask comprises a binary mask, a phase shifting mask, an alternating phase shifting mask, an attenuating phase shifting mask, a bright field mask, a dark field mask, an immersion lithography mask, or combinations thereof.

9. The lithography mask according to claim 7, wherein the at least one attenuation region comprises an array of features formed in a substantially opaque material disposed proximate a substantially transparent material.

10. The lithography mask according to claim 7, wherein the at least one attenuation region comprises an array of substantially transparent features formed in a substantially opaque material.

11. The lithography mask according to claim 7, wherein the at least one attenuation region comprises a first attenuation region adapted to reduce an amount of energy transmitted through the lithography mask proximate the first attenuation region by a first amount, and wherein the at least one attenuation region comprises at least one second attenuation region adapted to reduce an amount of energy transmitted through the lithography mask proximate the at least one second attenuation region by at least one second amount, the at least one second amount being different than the first amount.

12. A lithography system including the lithography mask according to claim 7.

13. A lithography mask, comprising:
a substantially opaque material; and
a substantially transparent material coupled to the substantially opaque material, wherein the substantially opaque material is patterned with at least one attenuation region comprising an array of energy-reducing features not reproducible on a layer of photosensitive material affected with the lithography mask.

14. The lithography mask according to claim 13, wherein the substantially opaque material is further patterned with a plurality of patterns proximate the at least one attenuation region, and wherein the plurality of patterns are reproducible on the layer of photosensitive material affected with the lithography mask.

15. The lithography mask according to claim 14, wherein the at least one attenuation region improves the patterning of the plurality of patterns proximate the at least one attenuation region.

16. The lithography mask according to claim 13, wherein the at least one attenuation region comprises an array of substantially opaque features formed in the substantially opaque material, or wherein the at least one attenuation region comprises an array of substantially transparent features formed in the substantially opaque material.

17. The lithography mask according to claim 13, wherein the at least one attenuation region comprises a plurality of attenuation regions, each of the plurality of attenuation regions being adapted to reduce an amount of energy transmitted through the lithography mask by a predetermined amount of energy, wherein the predetermined amount of energy reduction of each of the plurality of attenuation regions is the same or different than the predetermined amount of energy reduction of other of the plurality of attenuation regions.

18. A lithography system, comprising:
an energy source;
a projection lens system;
a lithography mask comprising at least one energy-attenuating region disposed between the energy source and the projection lens system; and
a support means for a semiconductor device, wherein when the lithography mask is used to pattern a layer of photosensitive material disposed on the semiconductor device, the at least one energy-attenuating region of the lithography mask reduces an amount of energy emitted from the energy source that passes through the at least one energy-attenuating region of the lithography mask, and wherein a pattern of the at least one energy-attenuating region of the lithography mask is not transferred to the layer of photosensitive material of the semiconductor device.

19. The lithography system according to claim 18, wherein the lithography system comprises an immersion lithography system, further comprising a means for disposing a fluid between the projection lens system and the semiconductor device.

20. The lithography system according to claim 18, wherein the lithography system comprises a lithography system that utilizes ultraviolet (UV) or extreme UV (EUV) light, an optical lithography system, an x-ray lithography system, an interference lithography system, or an immersion lithography system.

21. A method of manufacturing a lithography mask, the method comprising:
determining a layout for a material layer of a semiconductor device;
determining at least one area of the layout in which to form at least one energy-attenuating region;
determining an amount of energy reduction for the at least one energy-attenuating region;
determining a pattern for the at least one energy-attenuating region that will reduce energy transmitted through the lithography mask by the determined amount of energy reduction; and
including the pattern for the at least one energy-attenuating region in the layout of the material layer of the semiconductor device.

22. The method according to claim 21, wherein determining the pattern for the at least one energy-attenuating region comprises determining a pattern comprising an array of a plurality of opaque or transparent features.

23. The method according to claim 22, wherein determining the pattern comprising the array of a plurality of opaque or transparent features comprises determining a pattern for a plurality of square, round, elliptical, triangular, rectangular, polygonal, or trapezoidal features.

24. The method according to claim 23, wherein the plurality of opaque or transparent features comprises a width along at least one side of about 130 nm or less.

25. The method according to claim 23, wherein the plurality of opaque or transparent features comprise the same size within one area, are arranged in rows and columns, and are spaced apart by a first dimension d₁.

26. The method according to claim 25, further comprising determining a wavelength λ of energy of a lithography system the lithography mask will be implemented in, wherein determining the first dimension d₁ comprises solving for Equation 1:
d₁<(0.5*NA)/λ; Eq. 1
wherein NA is the numerical aperture of a projection lens system of the lithography system, and wherein λ is a wavelength used by an energy source of the lithography system during an exposure process.
